(19) United States
(12) Patent Application Publication
(10) Pub. No.: US 2003/0011395 A1
(43) Pub. Date: Jan. 16, 2003

(54) Method and system for determing an operating voltage using a STI induced scaling factor

(76) Inventor: Hyeon-Seag Kim, San Jose, CA (US)

Correspondence Address: Joseph A. Sawyer Jr., SAWYER LAW GROUP LLP, P. O. Box 51418, Palo Alto, CA, 94303, US

(21) Appl. No.: 09/888,213

(22) Filed: Jun. 22, 2001

(51) Int. Cl. G01R 31/26

(52) U.S. Cl. 324/765

(57) ABSTRACT

A method and system for determining an operating voltage for a semiconductor device is disclosed. The semiconductor device includes at least one silicon trench isolation (STI) structure and at least one active area. The method and system include determining a first plurality of lifetimes and a second plurality of lifetimes. The first plurality of lifetimes is determined for a first plurality of semiconductor devices having a first plurality of STI structures. The first plurality of semiconductor devices have a particular area of STI structures and a plurality of peripheral length of STI structures. The second plurality of lifetimes is determined for a second plurality of semiconductor devices having a second plurality of STI structures. The second plurality of semiconductor devices have a plurality of areas of STI structures and a particular peripheral length of STI structures. The method and system also include determining the operating voltage based on the first plurality of lifetimes and the second plurality of lifetimes.

### FIELD OF THE INVENTION

The present invention relates to semiconductor devices, and more particularly to a method and system for determining the operating voltage for a semiconductor device.

### BACKGROUND OF THE INVENTION

Silicon trench isolation structures are used to isolate different portions of a semiconductor device. For example, a flash memory device includes a core, which has memory cells, and a periphery, which includes other devices. The devices in the periphery include high voltage devices, such as charge generating circuits, and low voltage devices, such as amplifiers or control circuits. Separating the devices at the periphery, the cells at the core and other structures are isolation structures. Typically, these isolation structures are semiconductor trench isolation structures.

FIG. 1A depicts a conventional semiconductor device 10. The semiconductor device 10 includes an active area 12 where devices, such as memory cells and/or logic, are formed. Surrounding the active area 12 are silicon trench isolation structures (STIs) 14 that separate the active area 12 from the remainder of the semiconductor device 16. The semiconductor device 10 also includes other STIs (not shown in FIG. 1A).

FIG. 1B depicts a portion of the active are 12 of the conventional semiconductor device 10. The conventional semiconductor device 10 is a memory device, such as a Flash memory device. The conventional semiconductor device 10 includes memory cells, such as the memory cell 20 having a tunneling barrier 22. The conventional STI structure 24 separates the memory cell 20 from the device 30 having an insulating layer 32. Another STI structure 34 isolates the device 30 from the device 40 having an insulating layer 42. Also shown is an isolation structure 44.

Although the conventional semiconductor device 10 functions, one of ordinary skill in the art will readily recognize that the STI structures 12, 24, 34, and 44 may have thinned areas. FIG. 1C depicts a close up view of the conventional isolation structures 34 and 44, and device 40. Although only conventional STI structures 34 and 44 are depicted in FIG. 1C, the thinning in the STI structures 34 and 44, described below, can occur for any of the STI structures 12, 24, 34 and 44 of the conventional semiconductor device 10. The conventional STI structures 34 and 44 include conventional trenches 31 and 41, respectively, that are filled with conventional oxide fillers 33 and 43, respectively. Near the corners 35, 36, 45 and 46 of the conventional STI structures 34 and 44, the oxide filler 33 and 43 has thinned areas 38, 39, 48 and 49. The thinned areas 38, 39, 48 and 49 reduce the ability of the conventional STI structures 34 and 44 to insulate devices 30 and 40. As a result, a leakage current can occur through the thinned areas 38, 39, 48 and 49. The leakage current can lower the threshold voltage of devices fabricated near the conventional STI structures 34 and 44, which adversely affect performance of the conventional semiconductor device 30.

The thinned areas 38, 39, 48 and 49 may occur for a variety of reasons. Typically, silicon wafers having a (100) orientation (shown in FIG. 1C) are used for fabricating conventional semiconductor devices 10. Because the top surface has a (100) orientation, near the corners of the trenches 31 and 41, the exposed silicon has a (111) orientation. The (111) orientation of silicon has a larger number of dangling bonds. Thus, when the oxide filler 33 and 43 is provided, areas near the (111) orientation are thinner. In addition, mechanical stress tends to concentrate at areas where a corner is fabricated. Mechanical stress also tends to cause a thinning of the oxide filler 33 and 43 near the corners 35, 36, 45 and 46 of the conventional STI structures 34 and 44. In addition, as discussed above, in more recent conventional Flash memory devices, a nitride oxide, such as N₂O is used in forming the gate oxide for the memory cells 30 in the core region 40. When N₂O is used, the thinning that results in the areas 38, 39, 48 and 49 is even more severe. Thus, the problems due to leakage current in the devices 52 and 62 are made worse.

FIG. 2 depicts a high-level flow chart of a conventional method 50 for determining an operating voltage for the conventional semiconductor device 10. The lifetime of the conventional semiconductor device is determined, via step 52. Typically step 52 includes using a time dependent dielectric breakdown (“TDDB”) test and/or a voltage ramp dielectric breakdown (“VRDB”) test on a particular conventional semiconductor device 10. The TDDB test applies a particular voltage to the conventional semiconductor device 10 until the conventional semiconductor device 10 fails. The VRDB test applies an increasing voltage, typically one that increases in steps, to the conventional semiconductor device 10 until the conventional semiconductor device 10 fails. Thus, using step 52, the lifetime of the conventional semiconductor device 15, including the dependence of the lifetime on the operating voltage, can be determined.

The maximum operating voltage of the conventional semiconductor device 10 is then determined for the desired lifetime, via step 54. Thus, using the lifetimes determined in step 52, the maximum voltage that the semiconductor device can be operated at and still last for the desired time. During operation, an operating voltage that is less than or equal to the maximum operating voltage is utilized, via step 56. As a result, the conventional semiconductor device 10 should last for the desired amount of time. For example, it is typically desired to have a lifetime of ten years during use. The operating voltage used and the maximum operating voltage allowed to be used with the conventional semiconductor device 10 are set using the method 50 so that the lifetime of the conventional semiconductor device 10 is as desired.

Although the conventional method 50 functions, one of ordinary skill in the art will readily realize that the STI structures in 12, 24, 34 and 44 the conventional semiconductor device 10 will affect the life time at a particular operating voltage. In particular, the thinning at the corners of the STI structures, such as the thinned areas 38, 39, 48 and 49 adversely affect the lifetime of the conventional semiconductor device 10. However, the method 50 does not take into account the effect the STI structures 12, 24, 34 and 44 have on the lifetime of the semiconductor device. Furthermore, the method 50 does not take into account the effect that different configurations of the STI structures 12, 24, 34 and 44 could have on the lifetime of the conventional semiconductor device. For example, the method 50 does not take into account any differences in the lifetime of the conventional semiconductor device 10 due to the lengths of the STI structures 12, 24, 34 and 44. Thus, different configurations of the STI structures 12, 24, 34 and 44 may result in a conventional semiconductor device 10 having a lifetime that is different than expected for a particular operating voltage.

Accordingly, what is needed is a system and method for determining the operating voltage of the semiconductor device that takes into account the STI structures. The present invention addresses such a need.

### SUMMARY OF THE INVENTION

The present invention provides a method and system for determining an operating voltage for a semiconductor device. The semiconductor device includes at least one silicon trench isolation (STI) structure and at least one active area. The method and system comprise determining a first plurality of lifetimes and a second plurality of lifetimes. The first plurality of lifetimes is determined for a first plurality of semiconductor devices having a first plurality of STI structures. The first plurality of semiconductor devices have a particular area of STI structures and a plurality of peripheral length of STI structures. The second plurality of lifetimes is determined for a second plurality of semiconductor devices having a second plurality of STI structures. The second plurality of semiconductor devices have a plurality of areas of STI structures and a particular peripheral length of STI structures. The method and system also comprise determining the operating voltage based on the first plurality of lifetimes and the second plurality of lifetimes.

According to the system and method disclosed herein, the present invention provides a method and system for determining the maximum operating voltage for a semiconductor device that takes into account the effects of STI structures.

### BRIEF DESCRIPTION OF THE DRAWINGS

FIG. 1A is a high-level diagram of a conventional semiconductor device.

FIG. 1B is a more detailed diagram of a portion of the active area of the conventional semiconductor device.

FIG. 1C is a more detailed diagram of a portion of the active area including the conventional isolation structures.

FIG. 2 is a flow chart depicting a conventional method for determining an operating voltage for the conventional semiconductor device.

FIG. 3 is a high-level flow chart depicting one embodiment of a method in accordance with the present invention for determining an operating voltage for a semiconductor device.

FIGS. 4A-C depict different semiconductor devices that can be used in the method in accordance with the present invention for determining an operating voltage for a semiconductor device.

FIGS. 5A-C depict different semiconductor devices that can be used in the method in accordance with the present invention for determining an operating voltage for a semiconductor device.

FIG. 6 depicts one embodiment of a method in accordance with the present invention for scaling the operating voltage based on the STI structures.

FIG. 7 depicts the lifetime versus STI length and area of the active area for one embodiment of the method in accordance with the present invention for determining an operating voltage for a semiconductor device.

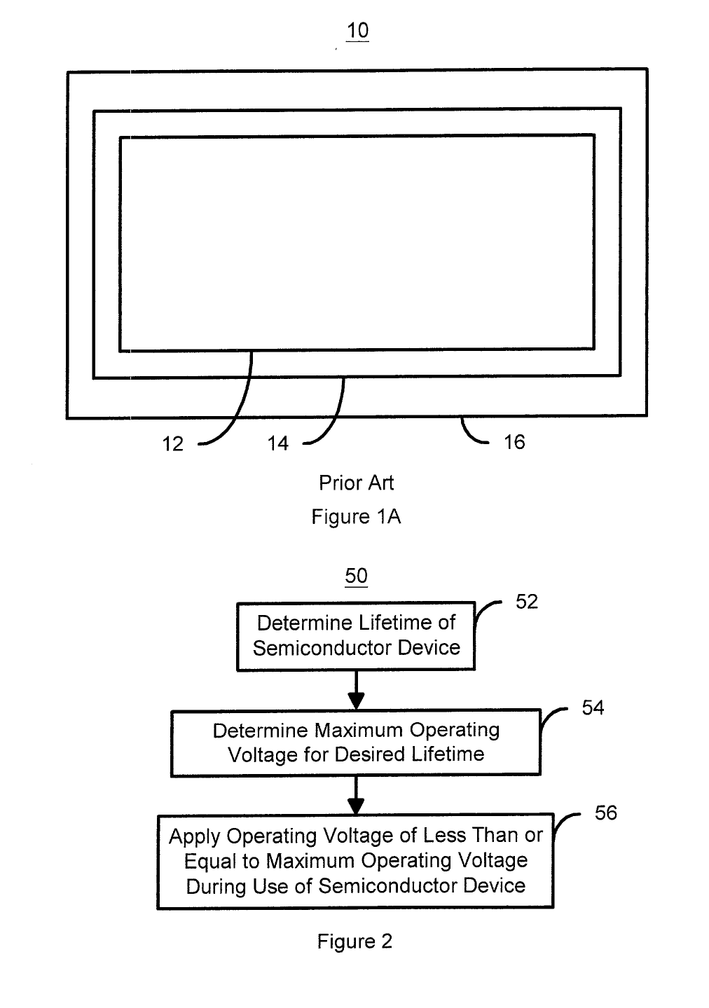

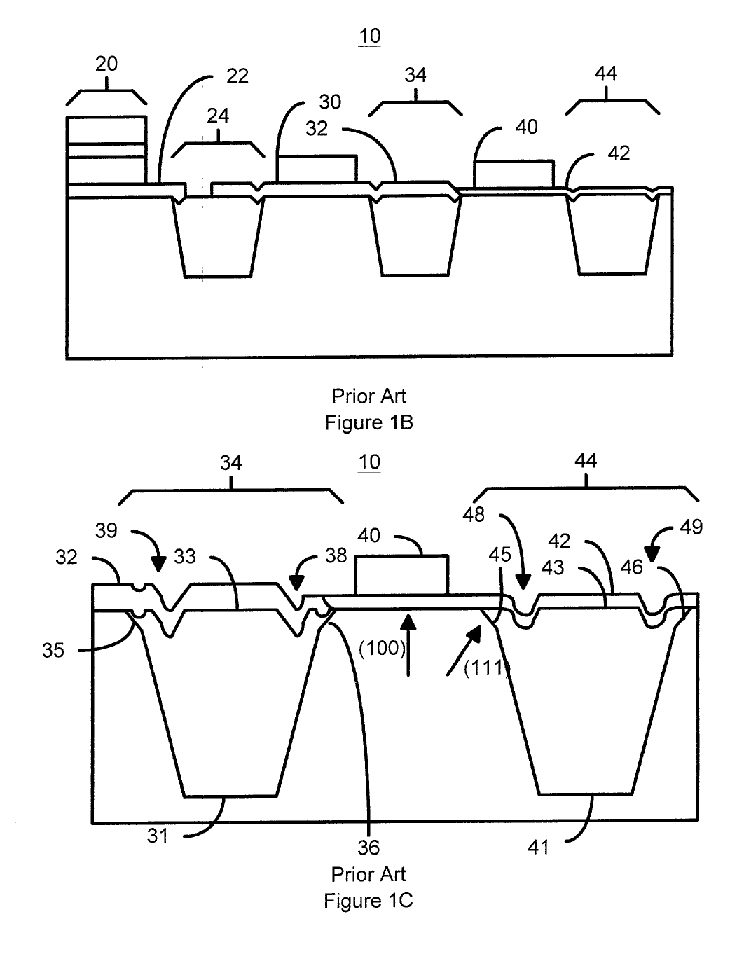

### DETAILED DESCRIPTION OF THE INVENTION

The present invention relates to an improvement in semiconductor devices. The following description is presented to enable one of ordinary skill in the art to make and use the invention and is provided in the context of a patent application and its requirements. Various modifications to the preferred embodiment will be readily apparent to those skilled in the art and the generic principles herein may be applied to other embodiments. Thus, the present invention is not intended to be limited to the embodiment shown, but is to be accorded the widest scope consistent with the principles and features described herein.

The present invention provides a method and system for determining an operating voltage for a semiconductor device. The semiconductor device includes at least one silicon trench isolation (STI) structure and at least one active area. The method and system comprise determining a first plurality of lifetimes and a second plurality of lifetimes. The first plurality of lifetimes is determined for a first plurality of semiconductor devices having a first plurality of STI structures. The first plurality of semiconductor devices have a particular area of STI structures and a plurality of peripheral length of STI structures. The second plurality of lifetimes is determined for a second plurality of semiconductor devices having a second plurality of STI structures. The second plurality of semiconductor devices have a plurality of areas of STI structures and a particular peripheral length of STI structures. The method and system also comprise determining the operating voltage based on the first plurality of lifetimes and the second plurality of lifetimes.

The present invention will be described in terms of a particular semiconductor device and certain STI structures. One of ordinary skill in the art will, however, recognize that the present invention can be used with other semiconductor devices and other isolation structures.

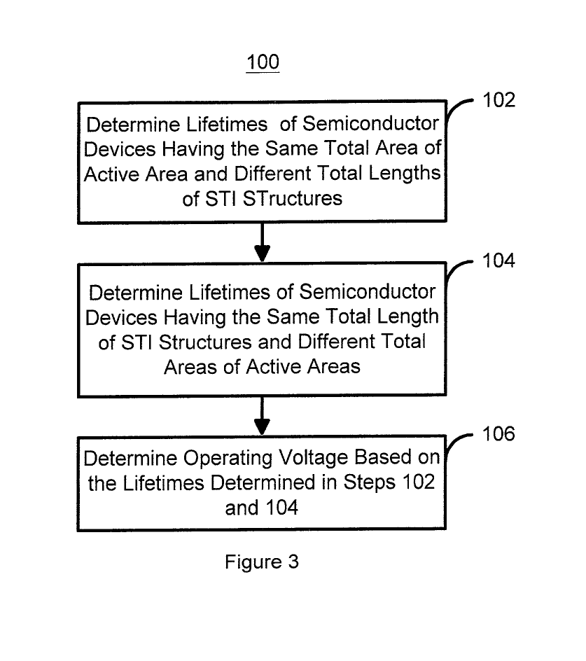

To more particularly illustrate the method and system in accordance with the present invention, refer now to FIG. 3, depicting one embodiment of a method 100 in accordance with the present invention for determining an operating voltage for a semiconductor device. The semiconductor device has an active area and STI structures. The lifetimes for the semiconductor device are determined for a particular active area with varying lengths of STI structures, via step 102. Preferably, at least three different lengths of STI structures are used in step 102. In determining the lifetimes, the TDDB and/or VRDB tests may be used. The VRDB test is faster. However, the TDDB test provides a better prediction of the lifetime of the semiconductor device under actual operating conditions. The lifetime of one of the devices, having a particular length and a particular area is typically calculated by using the fact that the lifetime of the test device, tₑₓₚ, is given by:

tₑₓₚ=A10^{(BE)} (1)

where:

| | | |
|---|---|---|
| A | = | constant |
| B | = | field acceleration factor for the device |
| E | = | applied field the device |

The field acceleration factor, B, can be determined using the slope of the curve formed by plotting the lifetime of the device versus the applied voltage. Similarly, an activation energy, Ea, that is discussed below can be determined for the device by plotting the lifetime of the device versus the temperature at which the tests are conducted. The actual lifetime of the device is then given by:

T=tₒₙₒ[exp{(Eₐ/k)(Tₒₚ+273)⁻¹−(Tₜₑₛₜ+273)⁻¹)}] (2)

where:

| | | |
|---|---|---|
| t | = | expected lifetime of device |
| | = | Ae^{(BE)} |
| E | = | applied field for the device |
| | = | Vₘₐₓ/χ_{eff} |
| Vₘₐₓ | = | Maximum applied voltage, or operating voltage |
| χ_{eff} | = | effective thickness of the device |
| B | = | field acceleration factor for the device |
| Eₐ | = | activation energy of the device |
| k | = | Boltzman's constant |
| Tₒₚ | = | Operating temperature of device (in degrees C.) |
| Tₜₑₛₜ | = | Test temperature (usually higher than operating temp) |
| | | (in degrees C.) |

The effective thickness, X_{eff}, can be calculated using the VRDB test and using the following relationship:

V_{BD}(device)(50%)/T_{eff}=V_{BD}(device)/T_{eff}(50%) (3)

where

| | | |
|---|---|---|
| V_{BD}(device)(50%) | = | breakdown voltage at a cumulative failure rate |
| | | of 50% |
| V_{BD}(device) | = | actual breakdown voltage |
| T_{eff}(50%) | = | median thickness of device |
| T_{eff} | = | effective device thickness |
| | = | V_{BD}(device)(50%)T_{eff}(50%)/V_{BD}(device) |

Once these quantities are determined, the lifetime can be determined.

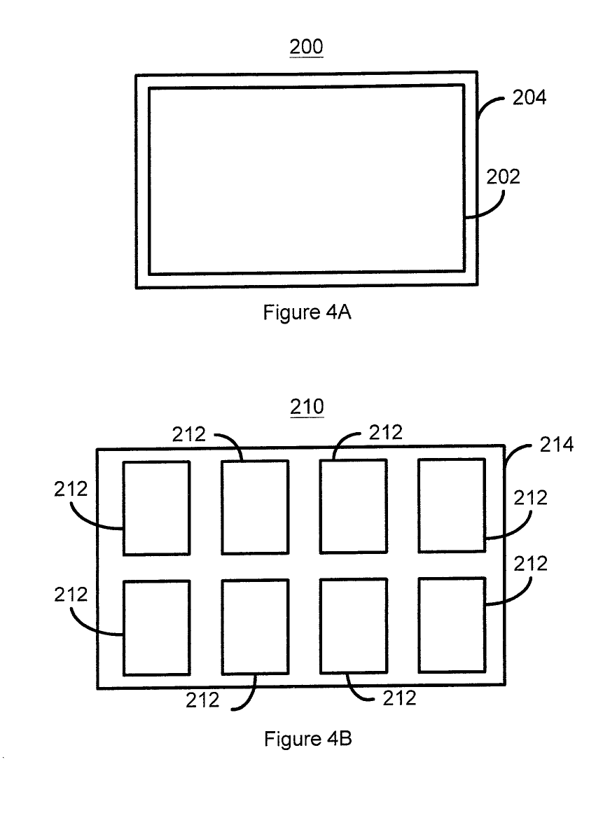

For example, FIGS. 4A-C depict three semiconductor device 200, 210 and 220. The active area 202, 212 and 222 has the same total area in each semiconductor device 200, 210 and 220, respectively. However, the STI structures 204, 214 and 224 have different total lengths. In one embodiment, the total active area is ten thousand square micrometers. However, lengths of the STI structures 204, 214 and 224 differ. For example, the length of the STI structures 202 is four times the length of a side of the active area 202. However, the length of the STI structures 214 is twice the total length of the active areas 212 plus five times the total height of the active areas. Thus, the lifetime for each of the semiconductor devices 200, 210 and 220 would be determined in step 102.

The lifetimes for the semiconductor device are determined for a particular length of STI structures and varying areas of the active area, via step 104. Preferably, at least three different lengths of STI structures are used in step 104. In determining the lifetimes, the TDDB and/or VRDB tests may be used. The VRDB test is faster. However, the TDDB test provides a better prediction of the lifetime of the semiconductor device under actual operating conditions. The lifetimes determined in step 104 would follow the relationships discussed above with respect to step 102.

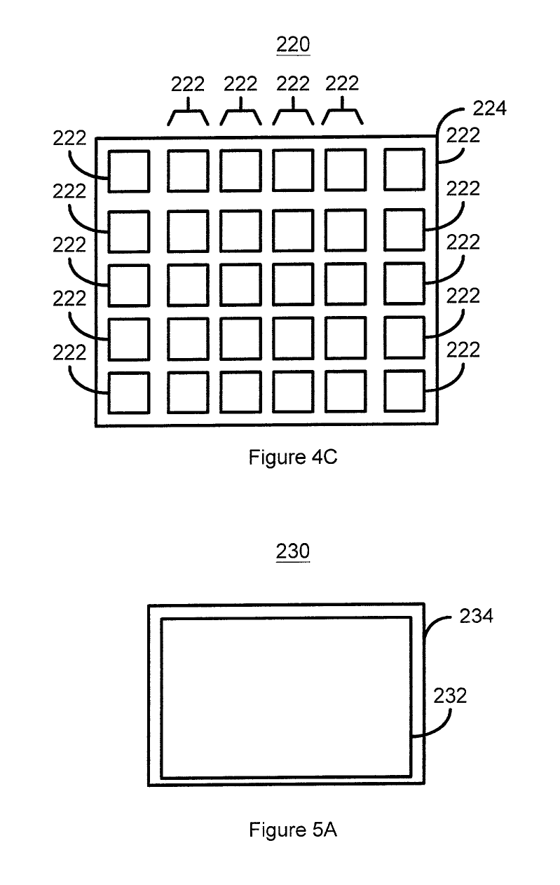

For example, FIGS. 5A-5C depict three semiconductor device 230, 240 and 250. The active areas 232, 242 and 252 has a different total area in each semiconductor device 230, 240 and 250, respectively. However, the STI structures 234, 244 and 254 have the same total lengths. In one embodiment, the total length is four hundred micrometers. However, areas of the active areas 232, 242 and 252 differ. Thus, the lifetime for each of the semiconductor devices 230, 240 and 250 would be determined in step 104.

Using the lifetimes determined in steps 102 and 104, an operating voltage that takes into account the area of the active area and length of STI structures is determined, via step 106. In a preferred embodiment, the operating voltage is a maximum operating voltage. Preferably, the operating voltage is determined using maximum voltage and equation (2) that delineates the relationship between the operating (or maximum) voltage and the lifetime. Preferably, step 106 includes determining the relationship between the lifetime and the length of the STI structures using the data from step 102 and determining the relationship between the lifetime and the total area of the active area using the data from step 104. These relationships can then be used to scale the operating voltage, particularly the maximum operating voltage, based on the configuration of the semiconductor device.

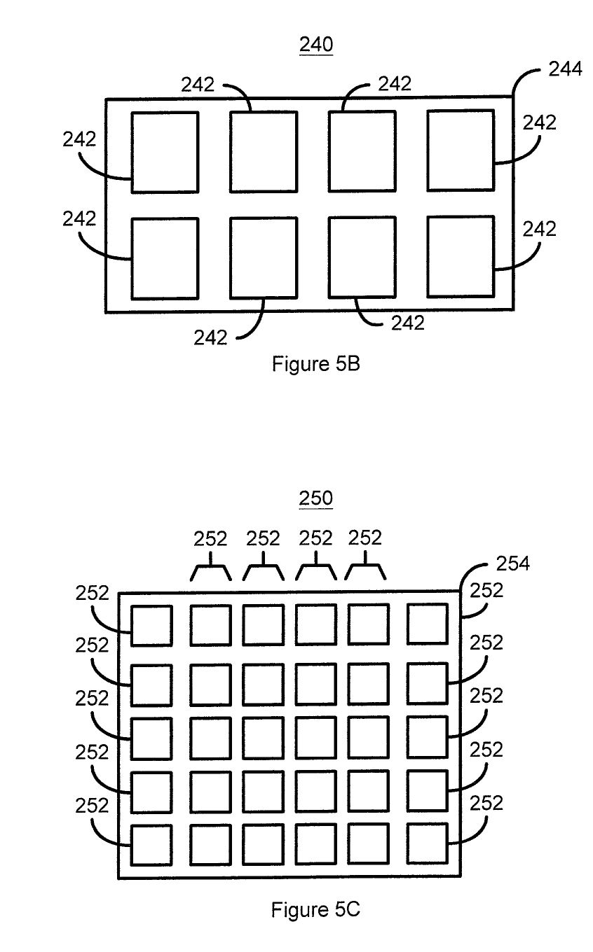

FIG. 6 depicts one embodiment of a method 110 in accordance with the present invention for determining the operating voltage based on the geometry of the device. Thus, the method 110 allows the area of the active area and length of the STI structures to be taken into account in determining the operating voltage. The worst case geometry for the device is determined, via step 112. Preferably, step 112 determines the geometry for which the lifetime will be the shortest. In addition, step 112 preferably utilizes an actual test geometry to determine the worst case geometry.

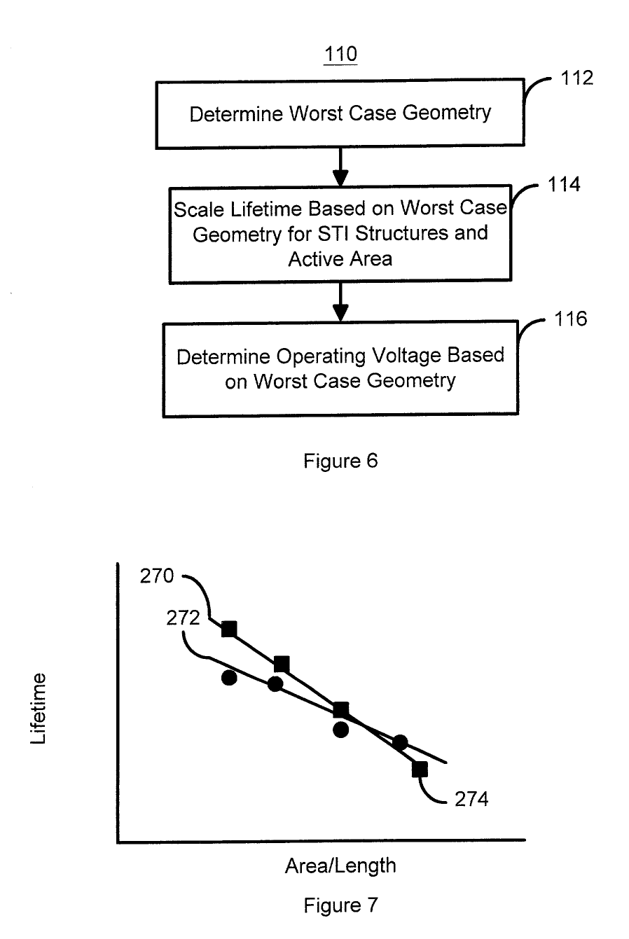

For example, FIG. 7 depicts the lifetime versus area of the active area 270 and lifetime versus length of the STI structure 272 for one embodiment of the method and system in accordance with the present invention. Using these curves 270 and 272, the worse case, or shortest lifetime, is selected to scale the lifetime and operating voltage with area and length. In the case of the curves 270 and 272, the worst combination resulting in the shortest lifetime is the largest area from the curve 270. Referring to FIGS. 6 and 7, the worst-case geometry determined in step 112 would thus preferably be the data point 274 of the worst case selected in step 112.

Referring back to FIG. 6, the lifetimes determined using the method 100 are scaled using the geometry selected in step 112 in order to account for the area of the active area and/or the length of the STI structures, via step 114. In order to do so, the lifetime can be scaled based on area, where the worst-case geometry is from a test device in which area was changed, or based on STI length, where the worst-case geometry is from a test device in which the STI length was changed. Where the lifetime is to be scaled based on the area in order to determine a lifetime for a product, the following relationship is used:

τ_{TD}/τₚ=A_{TD}/Aₚ (4)

where

| | | |
|---|---|---|
| τ_{TD} | = | lifetime of the test device |
| τₚ | = | scaled lifetime of the product being produced |
| A_{TD} | = | area of active area for the test device |
| Aₚ | = | area of active area for the product being produced |

Similarly, when the lifetime is to be scaled based on the STI length in order to determine a lifetime for a product, the following relationship is used:

τ_{TD}/τₚ=L_{TD}/Lₚ (5)

where

| | | |
|---|---|---|
| τ_{TD} | = | lifetime of the test device |
| τₚ | = | scaled lifetime of the product being produced |
| L_{TD} | = | length of STI structures for the test device |
| Lₚ | = | length of STI structures for the product being produced |

Once the lifetime has been scaled using the relationship in equation (4) or (5), the operating voltage is determined, via step 116. Step 116 preferably includes inputting the lifetime of the product that has been scaled, τₚ, into equation (2) and determining the maximum operating voltage, Vmax, based on the scaled lifetime. Thus, by scaling the lifetime based on the geometry which resulted in a worst-case lifetime, the operating voltage can be determined. In a preferred embodiment, the operating voltage so determined in step 116 is the maximum operating voltage. Thus, an operating voltage which takes into account the shape of the STI structures can be determined.

A method and system has been disclosed for determining an operating voltage for a semiconductor device. Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for determining an operating voltage for a semiconductor device including at least one silicon trench isolation (STI) structure and at least one active area, the method comprising the steps of:
(a) determining a first plurality of lifetimes for a first plurality of semiconductor devices having a first plurality of STI structures, the first plurality of semiconductor devices having a particular area of STI structures and a plurality of peripheral length of STI structures;
(b) determining a second plurality of lifetimes for a second plurality of semiconductor devices having a second plurality of STI structures, the second plurality of semiconductor devices having a plurality of areas of STI structures and a particular peripheral length of STI structures;
(c) determining the operating voltage based on the first plurality of lifetimes and the second plurality of lifetimes.

2. The method of claim 1 wherein the first plurality of lifetime determining step (a) further includes the steps of:
(a1) using a time dependent dielectric breakdown test in order to determine the first plurality of lifetimes.

3. The method of claim 1 wherein the second plurality of lifetime determining step (b) further includes the steps of:
(b 1) using a time dependent dielectric breakdown test in order to determine the second plurality of lifetimes.

4. The method of claim 1 wherein the first plurality of lifetime determining step (a) further includes the steps of:
(a1) using a voltage ramp dielectric breakdown test in order to determine the first plurality of lifetimes.

5. The method of claim 1 wherein the second plurality of lifetime determining step (b) farther includes the steps of:
(b1) using a voltage ramp dielectric breakdown test in order to determine the second plurality of lifetimes.

6. The method of claim 1 wherein the operating voltage is a maximum operating voltage.

7. The method of claim 1 wherein the operating voltage determining step (c) includes the steps of:
(c1) determining a particular geometry for the semiconductor device, the particular geometry corresponding to a particular lifetime;
(c2) scaling the particular lifetime to take into account an area of the active area and/or a peripheral length of the STI structures; and
(c3) determining the operating voltage based upon the scaled lifetime.

8. The method of claim 7 wherein the particular geometry is a worst-case geometry.

9. A method for operating a semiconductor device including at least one silicon trench isolation (STI) structure and at least one active area, the method comprising the steps of:
(a) applying an operating voltage, operating voltage being determined based on a first plurality of lifetimes and a second plurality of lifetimes, the first plurality of lifetimes being determined for a first plurality of semiconductor devices having a first plurality of STI structures, the first plurality of semiconductor devices having a particular area of STI structures and a plurality of peripheral length of STI structures, the second plurality of lifetimes being determined for a second plurality of semiconductor devices having a second plurality of STI structures, the second plurality of semiconductor devices having a plurality of areas of STI structures and a particular peripheral length of STI structures.

10. The method of claim 9 wherein the operating voltage is further determined by determining a particular geometry for the semiconductor device, the particular geometry corresponding to a particular lifetime, scaling the particular lifetime to take into account an area of the active area and/or a peripheral length of the STI structures, and determining the operating voltage based upon the scaled lifetime.

11. The method of claim 10 wherein the particular geometry is a worst-case geometry.
